(19) United States
(12) Patent Application Publication
(10) Pub. No.: US 2017/0026501 A1
(43) Pub. Date: Jan. 26, 2017

(54) MOBILE TERMINAL

(71) Applicants: Le Holdings (Beijing) Co., Ltd., Beijing (CN); LEMOBILE INFORMATION TECHNOLOGY (BEIJING) CO., LTD., Beijing (CN)

(72) Inventors: Dun Tian, Beijing (CN); Lianwei Xu, Beijing (CN)

(21) Appl. No.: 15/222,784

(22) Filed: Jul. 28, 2016

Related U.S. Application Data
(63) Continuation of application No. PCT/CN2016/082098, filed on May 13, 2016.

(30) Foreign Application Priority Data
Jul. 21, 2015 (CN) 201520533173.X

(51) Int. Cl. H04M 1/02; H01L 27/32; G02F 1/1333; G06F 3/041; F21V 8/00

(52) U.S. Cl. CPC H04M 1/0266; G06F 3/041; G02B 6/0073; G02F 1/13338; H01L 27/323

(57) ABSTRACT

The disclosure provides a mobile terminal including: a display screen, wherein a display surface of the display screen includes a display area and a non-display area; a transparent cover bonded to the display surface of the display screen, wherein a touch button facing the non-display area of the display screen is arranged on a surface of the transparent cover bonded to the display surface; a light guiding film arranged between the display screen and the transparent cover, the light guiding film covering the touch button and having a first end which extends out of the display screen; and a light source arranged opposite to an incident surface of the first end of the light guiding film. The mobile terminal according to an embodiment of the disclosure addresses the technical problem of a large gap between the display screen and the transparent cover in the prior art.

### CROSS-REFERENCE TO RELATED APPLICATIONS

This application is a continuation of International Application No. PCT/CN2016/082098, filed on May 13, 2016, designating the United States, and claiming priority to Chinese Patent Application No. 201520533173.X, filed with the Chinese Patent Office on Jul. 21, 2015 and entitled “Mobile terminal”, the content of which is hereby incorporated by reference in its entirety.

### TECHNICAL FIELD

The present disclosure relates to the field of touch buttons, and particularly to a mobile terminal.

### BACKGROUND

An existing mobile phone includes a liquid crystal display screen, a transparent cover arranged on one side of the liquid crystal display screen, a touch button arranged between the liquid crystal display screen and the transparent cover, and a backlight structure thereof including a light guiding film, a light source, etc. Touch button, the light guiding film, and the light source with a large thickness need to be accommodated between a gap between the liquid crystal display screen and the transparent cover, resulting in the problem of the large gap existing between the liquid crystal display screen and the transparent cover, which may discourage the mobile phone from becoming light-weighted and thinned.

In order to address the problem above, in the prior art, the touch button and the backlight structure thereof are removed from the liquid crystal display screen as illustrated in FIG. 1, where the liquid crystal display screen 10 is bonded to the transparent cover 20, the touch button 30 and the backlight structure 40 thereof are arranged on such a part of the surface of the transparent cover 20 that extends out of the liquid crystal display screen 10, and a display surface of the liquid crystal display screen 10 includes a display area 11 and a non-display area 12. Although the thickness of the mobile phone with above structure is small, such a new problem may occur that the height of the part of the transparent cover 20 extending out of the liquid crystal display screen 10 is so small, and there is a large distance between the touch button 30 arranged on the part, and the lower edge of the display area 11 on the display screen is large, that is, the touch button 30 as a whole is close to the bottom so that a user may perceive that the touch button 30 is positioned unduly, resulting in an unpleasing appearance of the

### SUMMARY

The disclosure provides a mobile terminal so as to address the technical problem of the large gap between the display screen and the transparent cover in the prior art.

The disclosure provides a mobile terminal including:

a display screen, wherein a display surface of the display screen includes a display area and a non-display area;

a transparent cover bonded to the display surface of the display screen;

a touch button facing the non-display area of the display screen and arranged on a surface of the transparent cover bonded to the display surface;

a light guiding film arranged between the display screen and the transparent cover, the light guiding film covering the touch button and having a first end which extends out of the display screen; and

a light source arranged opposite to an incident surface of the first end of the light guiding film.

Preferably a first end of the transparent cover may extend out of the display screen, and covers the light guiding film and the light source.

Preferably there may be a first area between the first end of the transparent cover and the display area, and the touch button may be arranged centrally in the first area in a first direction in which the first end of the transparent cover extends out of the display screen.

Preferably the light source may be a side-emitting organic light emitting diode (OLED).

Preferably the light source may be connected with a power source of the display screen.

Preferably the light guiding film may be affixed to the display surface of the display screen and/or the transparent cover.

Preferably the transparent cover may be a glass cover.

Preferably the display screen may be a flat display screen.

Preferably the display screen is a liquid crystal display screen or an organic light emitting diode display screen.

Preferably the mobile terminal may be a mobile phone or a tablet computer.

In the mobile terminal according to the disclosure, the transparent cover is bonded to the display surface of the display screen, and the touch button facing the non-display area of the display screen is arranged on the surface of the transparent cover bonded to the display surface; the light guiding film is arranged between the display screen and the transparent cover, the light guiding film covering the touch button and having the first end which extends out of the display screen; and the light source is arranged opposite to the incident surface of the first end of the light guiding film which extends out of the display screen, that is, the light source is arranged outside the display screen instead being arranged between the display screen and the transparent cover. As compared with the prior art, the voluminous light source is not arranged between the display screen and the transparent cover, so that there can be a smaller gap existing between the display screen and the transparent cover, which will encourage the mobile phone to become light-weighted and thinned.

### BRIEF DESCRIPTION OF THE DRAWINGS

In order to make the technical solutions according to the embodiments of the disclosure or in the prior art more apparent, the drawings to which a description of the embodiments or the prior art refers will be briefly introduced below, and apparently the drawings to be described below are merely illustrative of some of the embodiments of the disclosure, and those ordinarily skilled in the art can derive from these drawings other drawings without any inventive effort. In the drawings:

FIG. 1 is a schematic diagram of the mobile phone in the prior art;

FIG. 2 is a schematic internal structural diagram of a mobile terminal according to an embodiment of the disclosure; and

FIG. 3 is a schematic front view of the mobile terminal as illustrated in FIG. 2.

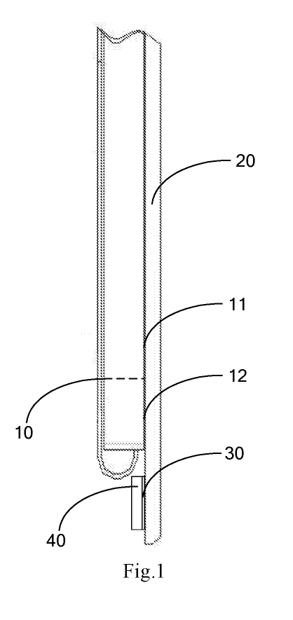

### REFERENCE NUMERALS

In the prior art:

10—Liquid crystal display screen, 11—Display area, 12—Non-display area, 20—transparent cover, 30—Touch button, 40—Backlight structure;

In the disclosure:

100—Display screen, 110—Display area, 120—Non-display area, 200—Transparent cover, 300—Touch button, 400—Light guiding film, 500—Light source

### DETAILED DESCRIPTION OF THE EMBODIMENTS

In order to make the objects, technical solutions, and advantages of the embodiments of the disclosure more apparent, the technical solutions according to the embodiments of the disclosure will be described below clearly and fully with reference to the drawings in the embodiments of the disclosure, and apparently the embodiments described below are only a part but not all of the embodiments of the disclosure. Based upon the embodiments here of the disclosure, all the other embodiments which can occur to those skilled in the art without any inventive effort shall fall into the scope of the disclosure.

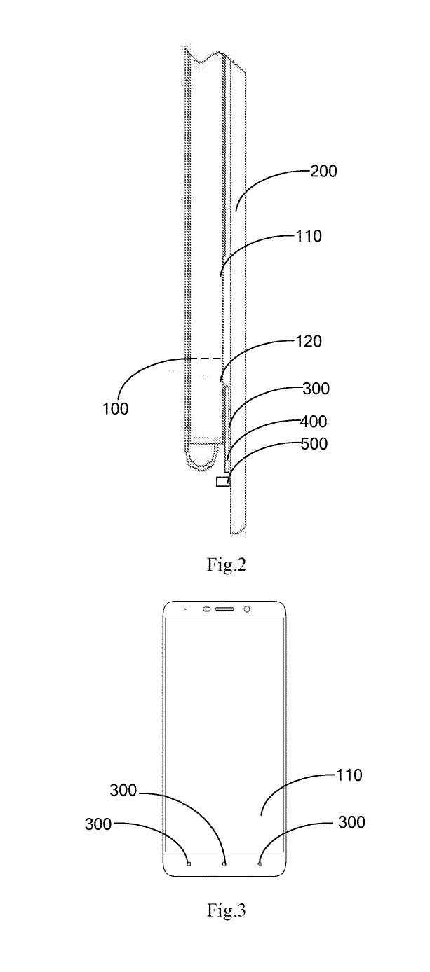

As illustrated in FIG. 2 and FIG. 3, a mobile phone according to an embodiment of the disclosure is provided. The mobile phone includes:

A display screen 100, where a display surface of the display screen 100 includes a display area 110 and a non-display area 120;

A transparent cover 200 bonded to the display surface of the display screen 100, where a touch button 300 facing the non-display area 120 of the display screen 100 is arranged on a surface of the transparent cover 200 bonded to the display surface;

A light guiding film 400 arranged between the display screen 100 and the transparent cover 200, the light guiding film 400 covering the touch button 300, and the light guiding film has a first end which extends out of the display screen 100; and

A light source 500 arranged opposite to an incident surface of the first end of the light guiding film 400.

In the mobile phone according to this embodiment, the transparent cover 200 is bonded to the display surface of the display screen 100, and the touch button 300 facing the non-display area 120 of the display screen 100 is arranged on the surface of the transparent cover 200 bonded to the display surface; the light guiding film 400 is arranged between the display screen 100 and the transparent cover 200, the light guiding film 400 covers the touch button 300, and the light guiding film 400 has the first end extending out of the display screen 100; and the light source 500 is arranged opposite to the incident surface of the first end of the light guiding film 400 extending out of the display screen 100, that is, the light source 500 is arranged outside the display screen 100 instead being arranged between the display screen 100 and the transparent cover 200. As compared with the prior art, the light source 500 which occupies large space is not arranged between the display screen 100 and the transparent cover 200, so that there can be a smaller gap arranged between the display screen 100 and the transparent cover 200, which will encourage the mobile phone to become light-weighted and thinned.

The transparent cover 200 facing a user needs to cover the other structural components of the mobile phone, so a first end of the transparent cover 200 extends out of the display screen 100, and covers the light guiding film 400, the light source 500, etc.

Furthermore as illustrated in FIG. 2 and FIG. 3, there is a first area between the first end of the transparent cover 200 and the display area 110, and the touch button 300 is arranged centrally in the first area in a first direction in which the first end of the transparent cover 200 extends out of the display screen 100.

Thus for the mobile phone, the first area is the non-display area on one side of the display area 110, and from the perspective of a pleasing appearance, the touch button 300 is arranged centrally in the first area in the first direction for a pleasing appearance of the mobile phone; and also the touch button 300 is arranged in the area of the transparent cover 200 facing the non-display area 120 of the display screen 100, which requires that the transparent cover 200 shall extend out of the display screen 100 by a small height, so that there may be a larger ratio of the area of the transparent cover 200 facing the display area 110 to the transparent cover 200, and thus a smaller height of the mobile phone under the same transparent cover 200.

Preferably the light source 500 is a side-emitting organic light emitting diode (OLED).

Preferably the side-emitting light source 500 is connected with a power source of the display screen 100, so that the light source can be provided with the power source.

Preferably the light guiding film 400 is affixed to the display surface of the display screen 100 and/or the transparent cover 200.

Preferably the transparent cover 200 is a glass cover.

Particularly the display screen 100 is a flat display screen, e.g., a liquid crystal display screen or an organic light emitting diode display screen.

It shall be noted that the embodiment has been described taking a mobile phone as an example, but in fact, it can be applicable to any other mobile terminal for which a touch button is required, e.g., a tablet computer, etc.

Lastly it shall be noted that the respective embodiments above are merely intended to illustrate but not to limit the technical solution of the disclosure; and although the disclosure has been described above in details with reference to the embodiments above, those ordinarily skilled in the art shall appreciate that they can modify the technical solution recited in the respective embodiments above or make equivalent substitutions to a part of the technical features thereof; and these modifications or substitutions to the corresponding technical solution shall also fall into the scope of the disclosure as claimed.

1. A mobile terminal, comprising:
a display screen, wherein a display surface of the display screen comprises a display area and a non-display area;
a transparent cover bonded to the display surface of the display screen;
a touch button facing the non-display area of the display screen and arranged on a surface of the transparent cover bonded to the display surface;
a light guiding film arranged between the display screen and the transparent cover, the light guiding film covering the touch button and having a first end which extends out of the display screen; and
a light source arranged opposite to an incident surface of the first end of the light guiding film.

2. The mobile terminal according to claim 1, wherein a first end of the transparent cover extends out of the display screen, and covers the light guiding film and the light source.

3. The mobile terminal according to claim 2, wherein there is a first area between the first end of the transparent cover and the display area, and the touch button is arranged centrally in the first area in a first direction in which the first end of the transparent cover extends out of the display screen.

4. The mobile terminal according to claim 1, wherein the light source is a side-emitting organic light emitting diode (OLED).

5. The mobile terminal according to claim 4, wherein the light source is connected with a power source of the display screen.

6. The mobile terminal according to claim 5, wherein the light guiding film is affixed to the display surface of the display screen and/or the transparent cover.

7. The mobile terminal according to claim 6, wherein the transparent cover is a glass cover.

8. The mobile terminal according to claim 7, wherein the display screen is a flat display screen.

9. The mobile terminal according to claim 7, wherein the display screen is a liquid crystal display screen or an organic light emitting diode display screen.

10. The mobile terminal according to claim 7, wherein the mobile terminal is a mobile phone or a tablet computer.

11. The mobile terminal according to claim 2, wherein the light source is a side-emitting organic light emitting diode (OLED).

12. The mobile terminal according to claim 3, wherein the light source is a side-emitting organic light emitting diode (OLED).
